(19) United States
(12) Patent Application Publication
(10) Pub. No.: US 2005/0053535 A1
(43) Pub. Date: Mar. 10, 2005

(54) Gettering filter and associated method for removing oxygen from a gas

(75) Inventors: David A. Beauchaine, Vancouver, WA (US); Oleg V. Kononchuk, Brush Prairie, WA (US)

Correspondence Address: ALSTON & BIRD LLP;BANK OF AMERICA PLAZA, 101 SOUTH TRYON STREET, SUITE 4000, CHARLOTTE, NC, 28280-4000, US

(73) Assignee: SEH America, Inc., Vancouver, WA (US)

(21) Appl. No.: 10/657,606

(22) Filed: Sep. 8, 2003

(51) Int. Cl. C01B 13/00; H01L 21/311

(52) U.S. Cl. 423/219; 438/694

(57) ABSTRACT

A method and apparatus are provided for removing oxygen and moisture from a gas such that wafers subsequently exposed to the gas develop less haze. The apparatus includes a process chamber for receiving a wafer. The apparatus also includes a gettering filter in fluid communication with the process chamber for removing oxygen from a gas that passes through the gettering filter in route to the process chamber. The gettering filter includes a vessel and a plurality of pieces of an oxidizable material disposed within the vessel. The oxidizable material is selected to oxidize upon exposure to oxygen in the gas such that the gas exiting the vessel has less oxygen than the gas entering the vessel. The oxidizable material may also be selected such that the resulting oxide layer is etchable upon exposure to an etchant, thereby permitting the gettering filter to be regenerated.

### FIELD OF THE INVENTION

The present invention relates generally to gettering filters and associated methods for removing contaminants from gas streams and, more particularly, to gettering filters and associated methods for removing oxygen from a gas stream, such as to reduce the haze formed on the surface of a wafer subsequently exposed to the gas stream.

### BACKGROUND OF THE INVENTION

Many processes require the supply of relatively pure gas with very low levels of contamination. For example, the process for fabricating wafers, such as silicon wafers, has a number of steps, many of which require the provision of relatively pure gas streams. By was of example, wafers are oftentimes annealed following the polishing of the wafers and prior to the final cleaning of the wafers. Among other advantages, this annealing reduces the flaws otherwise occasioned by crystal originated particles (COP). In order to anneal the wafers, the wafers are placed in a furnace and a non-reactive gas, such as nitrogen or argon, is flowed through the furnace while the wafers are heated. Unfortunately, in instances in which the gas that is flowed through the furnace contains oxygen, such as in the form of moisture, a haze may be formed on the surface of the wafers. By way of example, argon having a purity of 99.999% may still disadvantageously have up to 0.5 ppm of oxygen and 0.5 ppm of moisture.

As known to those skilled in the art, a haze generally consists of islands of oxide formed on respective portions of the surface of the wafers, thereby resulting in an uneven or inconsistent oxide layer on the surface of the wafers. While minimal amounts of haze may be tolerated without significantly adversely affecting the wafers, any substantial amount of haze causes the wafers to be scrapped. In this regard, the haze roughens the surface of the wafers such that the wafers cannot be reworked into an acceptable form in any cost efficient manner and, instead, must be scrapped. As such, the formation of haze on the surface of wafers as a result of oxygen in a gas flowed through the furnace increases the cost of the resulting wafers and decreases the yield of the fabrication process since wafers having an excessive amount of haze must be scrapped.

In order to remove at least some of the oxygen from the gas that is flowed through the furnace, purification getter devices are available. Conventional purification getter devices are positioned slightly upstream of the furnace such that the gas passes through the purification getter device prior to entering the furnace. For example, a Mono Torr Phase II purifier from SAES Getters, S.p.A. is a heated getter for removing impurities from rare gases, nitrogen and hydrogen. The Mono Torr Phase II purifier incorporates metal getter technology based on zirconium metals that form irreversible chemical bonds to remove oxide, carbide and nitride impurities. Unfortunately, the filter media is quite expensive and must be periodically replaced. For example, a replacement filter may cost about $8500.00 and may need to be replaced every six months to a year depending upon the use of the filter and the purity of the gas that is flowed therethrough. Additionally, the filter media is considered somewhat hazardous so as to complicate and accordingly increase the costs of handling and disposal.

Thus, it would be desirable to provide an improved method and apparatus for removing contaminants, such as oxygen, from a gas stream, such as to reduce the haze produced on the surface of wafers subsequently exposed to the gas stream and therefore reduce the number of wafers that must be scrapped as a result of having excessive haze. Moreover, it would be desirable to provide a method and apparatus for removing contaminants, such as oxygen, from a gas in a manner that is relatively inexpensive and does not require components that are hazardous.

### SUMMARY OF THE INVENTION

An improved method and apparatus are therefore provided according to embodiments of the present invention for removing oxygen and moisture from a gas. In one advantageous embodiment, the method and apparatus remove oxygen from a gas that is subsequently introduced into a process chamber and circulated about at least one wafer. By reducing the oxygen in the gas prior to the introduction of the gas into the process chamber, the resulting haze formed on the surface of the at least one wafer within the process chamber is reduced, thereby correspondingly reducing the number of wafers that must be scrapped and increasing the efficiency or yield of the wafer fabrication process. Advantageously, the method and apparatus of the present invention are relatively inexpensive and may be repeatedly utilized to remove oxygen from a gas.

According to one aspect of the present invention, an apparatus is provided that includes a process chamber, such as a furnace, for receiving at least one wafer. The apparatus also includes a gettering filter in fluid communication with the process chamber for removing oxygen from a gas that passes through the gettering filter in route to the process chamber. The gettering filter includes a vessel defining an inlet and an outlet through which the gas enters and exits, respectively. Typically, the vessel is formed of a material, such as quartz, that does not react with the gas. The gettering filter also includes a plurality of pieces of an oxidizable material disposed within the vessel. The oxidizable material is selected so as to oxidize upon exposure to oxygen in the gas such that the gas exiting the vessel through the outlet has less oxygen than the gas entering the vessel through the inlet.

In one embodiment, the oxidizable material is formed of the same material as the at least one wafer. For example, the oxidizable material may be formed of silicon. The oxidizable material may also be selected such that the oxide layer formed on the pieces of the oxidizable material as a result of the exposure of the pieces of oxidizable material to oxygen in the gas is etchable upon exposure to an etchant. Thus, the pieces of oxidizable material may periodically be regenerated by etchably removing at least some of the oxide layer that has been formed on the pieces of oxidizable material. Additionally, the variety of pieces of the oxidizable material generally have different sizes to facilitate the substantial filling of the vessel with the plurality of pieces of oxidizable material.

The gettering filter may also include a heater in thermal communication with the vessel to heat the plurality of pieces of the oxidizable material, thereby facilitating the oxidation of the plurality of pieces of oxidizable material upon exposure to oxygen in the gas. Typically, the heater is proximate to and at least partially surrounding the vessel. Regardless of its relative position, the heater of one embodiment maintains the plurality of pieces of the oxidizable material at a temperature between about 600° C. and about 1200° C. and, more typically, between about 600° C. and about 1000° C. Thus, the gettering filter effectively removes at least a portion of the oxygen from the gas prior to introduction of the gas to the process chamber, thereby reducing the haze formed on the wafers within the process chamber as a result of the oxygen in the gas.

According to another aspect of the present invention, an improved method of filtering a gas stream is provided. According to this method, gas is flowed through a vessel containing a plurality of pieces of an oxidizable material. While the gas is flowing through the vessel, an oxide layer is formed on at least some of the pieces of oxidizable material as a result of the exposure of the pieces of oxidizable material to oxygen in the gas. In order to facilitate the formation of the oxide layer on at least some of the pieces of the oxidizable material, the plurality of pieces of the oxidizable material may be heated while flowing gas through the vessel. In this regard, the plurality of pieces of the oxidizable material may be heated to a temperature between about 600° C. and about 1200° C. and, more typically, between about 600° C. and about 1000° C.

After the gas has flowed through the vessel, the gas is introduced into a process chamber, such as a furnace, containing at least one wafer. Since the gas has previously flowed over at least some of the pieces of the oxidizable material, the gas introduced to the process chamber has less oxygen than the gas entering the vessel, thereby correspondingly reducing the haze formed on the surface of the wafers within the process chamber and similarly reducing the number of wafers that must be scrapped for having excessive haze.

According to one advantageous method, the flow of gas through the vessel may periodically be halted and the plurality of pieces of the oxidizable material may be etched to at least partially remove the oxide layer while the flow of gas through the vessel is halted. In this regard, the plurality of pieces of the oxidizable material may be exposed to an etchant. In one exemplary embodiment in which the plurality of pieces of oxidizable material are formed of silicon, the etchant may be hydrofluoric acid which effectively etchably removes silicon oxide from the plurality of pieces of silicon. Once the plurality of pieces of oxidizable material have been etched, the flow of gas through the vessel may be recommenced. By periodically etchably removing the oxide layer that has been formed on at least some of the pieces of oxidizable material, the filtering efficiency of the oxidizable material may be regenerated. As such, the gettering filter and associated method of the present invention may be utilized to remove oxygen from gas streams indefinitely since any significant reduction in the efficiency with which the gettering filter removes oxygen from the gas stream as a result of the oxide layer formed on at least some of the pieces of the oxidizable material is remedied by the periodic etching of the oxidizable material.

Accordingly, the method and apparatus of the invention effectively remove oxygen from a gas prior to the introduction of the gas into a process chamber in order to reduce the haze formed on the surface of the wafer, thereby reducing the number of wafers that must be scrapped for excessive haze and correspondingly advantageously increasing the yield of the wafer fabrication process. Additionally, the gettering filter of the present invention is generally relatively inexpensive and does not include any components that are hazardous so as to simplify handling of the gettering filter.

### BRIEF DESCRIPTION OF THE DRAWING(S)

Having thus described the invention in general terms, reference will now be made to the accompanying drawings, which are not necessarily drawn to scale, and wherein:

FIG. 1 is a schematic representation of an apparatus according to one embodiment of the present invention which illustrates a gettering filter disposed upstream of a process chamber; and

FIG. 2 is a schematic representation of a gettering filter according to one embodiment of the present invention.

### DETAILED DESCRIPTION OF THE INVENTION

The present inventions now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

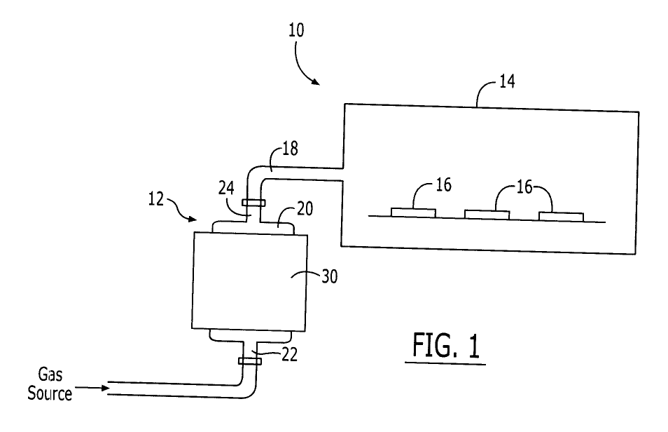

Referring now to FIG. 1, an apparatus 10 according to one embodiment of the present invention is depicted. The apparatus includes a gettering filter 12 that is designed to remove oxygen from a gas stream. The gettering filter receives the gas stream from any suitable gas supply and at any desired flow rate. Although the gas that is supplied to the gettering filter is generally relatively pure, the gas may include some contaminants, such as oxygen, which may be in the form of moisture, that may adversely affect downstream processing activities. As shown in FIG. 1, the apparatus also includes a process chamber 14 for receiving the gas once the gas has passed through and been filtered by the gettering filter. Thus, the gas that is provided to the process chamber has increased purity, as a result of having fewer contaminants, such as less oxygen, than the gas that is supplied to the gettering filter.

The apparatus 10 and method of the present invention may be utilized in a variety of applications. By way of example and not of limitation, however, the method and apparatus of the present invention will be hereinafter described in conjunction with the purification of gas supplied to a process chamber 14 in which at least one wafer 16 and, more typically, a plurality of wafers, such as silicon wafers, are disposed. As this example indicates, the method and apparatus of the present invention are therefore advantageous for purifying the gas utilized during the various steps of a wafer fabrication process. In this regard, the process chamber may be a furnace, such as a diffusion furnace or an anneal type furnace as utilized to anneal wafers during a wafer fabrication process. As known to those skilled in the art, wafers are typically annealed following the polishing of the wafers and prior to the final cleaning of the wafers in order to reduce the deleterious effects of COP. During the annealing process, a non-reactive gas is flowed over the wafers. Typically the gas is nitrogen or argon, although other gases and, in particular, other inert gases, may be flowed through the furnace.

In order to remove oxygen from the gas prior to its introduction into the process chamber 14 and to correspondingly reduce the haze that would otherwise be formed upon the surface of the wafers 16 within the process chamber, the gettering filter 12 removes at least some of the oxygen and moisture (hereinafter collectively referred to as “oxygen”) from the gas prior to its introduction into the process chamber. The gettering filter is advantageously disposed at the point of use, such as immediately upstream of the process chamber and, in one embodiment, is disposed about two feet from the process chamber and is fluid communication therewith via a conduit 18. However, the gettering filter may be disposed either closer to or further from the process chamber so long as the gettering filter is in fluid communication with the process chamber by means of a conduit or the like that does not permit additional oxygen to be re-introduced into the gas stream following its purification by the gettering filter.

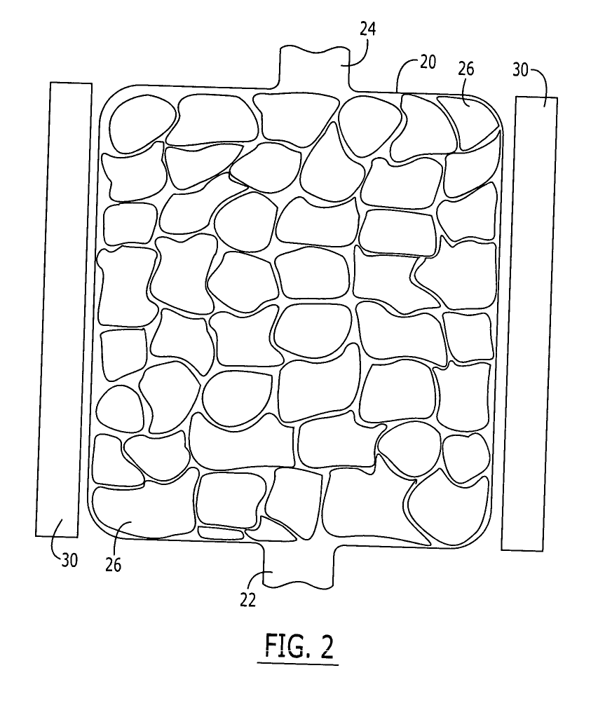

As shown in more detail in FIG. 2, the gettering filter 12 includes a vessel 20 defining an inlet 22 and an outlet 24 through with the gas enters and exits, respectively. As shown in FIG. 2, the vessel may have a generally cylindrical shape with the inlet and the outlet defined by the opposite ends thereof. However, the vessel may have other configurations without departing from the spirit and the scope of the present invention. Likewise, the vessel may define the inlet and outlet at other relative locations, although the inlet and outlet are preferably positioned in an opposed relationship relative to one another such that a gas entering the vessel through the inlet must pass through the internal cavity defined by the vessel prior to exiting the vessel through the outlet. As shown in FIGS. 1 and 2, the vessel may be disposed in a vertical orientation such that the inlet and outlet are defined by the bottom and top, respectively, of the vessel. However, the vessel may be disposed in other orientations, such as a horizontal orientation or any other orientation, without departing from the spirit and scope of the present invention.

The vessel 20 is advantageously formed of a material that does not react, at least not to any significant degree, with the gas that flows through the vessel. In one embodiment, for example, the vessel is formed of quartz. Additionally, the vessel may have various shapes and sizes. In the illustrated embodiment, the vessel is generally cylindrical with a length of 10 inches and a diameter of 5 inches. However, larger vessels may be employed to permit additional oxygen to be removed from the gas, and smaller vessels may be employed if only limited amounts of oxygen are to be removed from the gas.

The gettering filter 12 also includes a plurality of pieces 26 of an oxidizable material disposed within the vessel 20. As described below, the oxidizable material is selected so as to oxidize upon exposure to oxygen in the gas that is flowed through the vessel. By oxidizing upon exposure to the oxygen (including moisture) in the gas flowing through the vessel, oxygen is removed from the gas flowing through the vessel such that the gas exiting the vessel through the outlet 24 has less oxygen than the gas entering the vessel through the inlet 22. Since the gas exiting the vessel through the outlet is thereinafter introduced into the process chamber 14 and flowed over the wafers 16, the gas introduced into the process chamber and flowed over the wafers correspondingly has less oxygen than the gas entering the vessel through the inlet as a result of the oxidation of the plurality of pieces of oxidizable material disposed within the vessel of the gettering filter.

The oxidizable material may be formed of different materials so long as the material is capable of oxidizing, as its name suggests. Preferably, the oxidizable material is non-metallic, thereby eliminating any risk that metallic particles could propagate from the vessel into the process chamber 14 and be deposited upon the wafers 16 as a containment. In this regard, the oxidizable material of one advantageous embodiment is formed of the same material as the wafers within the process chamber. Thus, any particles of the oxidizable material that propagate from the vessel to the process chamber will be undesirable particulates, but will not be even more undesirable contaminants. For example, the oxidizable material may be formed of silicon, in instances in which the wafers within the process chamber are also formed of silicon. For example, the oxidizable material may be formed of pieces 26 of polycrystalline silicon, such as the same type of polysilicon that is utilized to form the melt from which a silicon ingot is drawn.

The pieces 26 of the oxidizable material may have various sizes and shapes. For example, the pieces of the oxidizable material may be spherical in shape and may have either the same or different diameters. By way of illustration, spherical pieces of oxidizable material may have diameters between about 0.5 inch and about 1 inch. More commonly, however, the pieces of the oxidizable material are relatively irregular in shape. Regardless of the shape, the pieces of the oxidizable material are typically larger than the inlet 22 and the outlet 24 of the vessel 20 such that the pieces of oxidizable material cannot escape the vessel. However, the inlet and the outlet may be larger than at least some of the pieces of the oxidizable material and a porous member, such as a screen or the like, may be placed over the inlet and/or the outlet to prevent these smaller pieces of oxidizable material from escaping through the inlet or the outlet or otherwise becoming lodged in the inlet or the outlet.

To facilitate the removal of oxygen from the gas passing through the vessel 20, the gas is preferably exposed to as large of a surface area of the oxidizable material as possible. However, the pieces 26 of oxidizable material must be sufficiently loosely packed such that the desired flow rate of the gas to the process chamber 14 may be maintained. While various flow rates may be established depending upon the requirements of the downstream process, a flow rate of between about 30 liters per minute and 50 liters per minute is commonplace. To maintain this range of flow rate, the pieces of oxidizable material cannot be tightly packed. However, pieces of oxidizable material having generally two sizes, namely, a larger size and a smaller size, may be utilized to fill the vessel with the smaller pieces of the oxidizable material generally partially filling voids that otherwise would exist between larger adjacent pieces of the oxidizable material.

In order to facilitate the oxidation of the pieces 26 of oxidizable material upon exposure to oxygen in the gas flowing through the vessel 20, the pieces of oxidizable material may be heated. While the pieces of oxidizable material may be heated in various manners, the gettering filter 12 of one embodiment includes a heater 30 that is positioned in thermal communication with the pieces of oxidizable material. As shown in FIGS. 1 and 2, the heater may be external to and proximate the vessel. The heater extends circumferentially about the vessel and, while the heater may extend along only a portion of the vessel, the heater typically extends along the entire length of the vessel. While various types of heaters may be utilized, one suitable heater is a resistance coil that is insulated and wrapped about the vessel. The heater may warm the pieces of oxidizable material to various temperatures to facilitate their oxidation. In one embodiment, however, the heater is configured to warm the pieces of oxidizable material to a temperature between about 600° C. and about 1200° C. and, more particularly, to between about 600° C. and about 1000° C. Moreover, the temperature of the pieces of oxidizable material could be gradually increased as an oxide layer is formed upon the oxidizable material with the increased temperature at least somewhat offsetting the decrease in the efficiency with which the oxidizable material otherwise removes oxygen from the gas as an oxide layer is formed thereupon.

In operation, the pieces 26 of the oxidizable material, such as irregular pieces of polysilicon, are placed within the vessel 20. While the vessel could be designed to have an opening through which the pieces of oxidizable material are inserted, the pieces of oxidizable material are generally placed in the vessel as the vessel is being formed, such as prior to fusing one of the ends onto the remainder of the vessel. Alternatively, the inlet 22 and/or the outlet 24 could be sized to permit the pieces of oxidizable material to be inserted therethrough. The vessel is then connected in line between the supply of gas and the process chamber 14, such as by means of conventional connections between respective conduits 18 and the inlet and outlet of the vessel. After wafers 16, such as silicon wafers, have been placed within the process chamber, the process chamber is appropriately heated and gas is supplied by the gas supply so as to flow through the vessel and, in turn, into the process chamber. Additionally, the pieces of oxidizable material are generally heated to facilitate oxidation, as described above.

As the gas flows through the vessel 20, an oxide layer is formed on at least some of the pieces of the oxidizable material as a result of the exposure of the pieces 26 of oxidizable material to oxygen (including moisture) in the gas. Thus, the gas introduced into the process chamber 14 has less oxygen than the gas entering the vessel 20 as a result of the formation of the oxide layer on at least some of the pieces of the oxidizable material. By reducing the oxygen in the gas that flows through the process chamber, the wafers will have less haze and therefore the yield of the wafer fabrication process will be enhanced.

The efficiency with which the pieces 26 of oxidizable material remove oxygen from the gas passing through the vessel 20 will diminish as the oxide layer builds up on the pieces of oxidizable material. The decrease in the efficiency with which oxygen is removed from the gas can be detected in various manners including by measuring the oxygen or moisture entering the process chamber 14 with an oxygen or moisture detector proximate the inlet to the process chamber. Alternatively, and advantageously, in embodiments in which silicon is the oxidizable material, one may take advantage of the color change exhibited by silicon as an oxide layer is grown thereupon. In this regard, the color of the pieces of silicon proximate the inlet 22 could be examined and compared to the color of pieces of silicon proximate the outlet 24. In instances in which the color of the pieces of silicon changes between the inlet and the outlet, the operator could be alerted to the build up of an oxide layer on at least some of the pieces of silicon and the corresponding decrease in the gettering efficiency. Since the pieces of silicon will simply glow red while heated during normal operation of the gettering filter 12, the gettering filter would need to be removed from service and cooled to determine if the color of the pieces of silicon vary from the inlet to the outlet. In order to regenerate the gettering filter so as to improve the efficiency with which the pieces of oxidizable material will remove oxygen from the gas passing through the vessel, the pieces of oxidizable material may be exposed to an etchant which at least partially removes the oxide layer formed on the pieces of oxidizable material. As such, the oxidizable material is preferably selected such that the resulting oxide layer is etchable upon exposure to an etchant. In this regard, the oxidizable material may be silicon such that silicon oxide is formed on the surface of the pieces of silicon upon exposure to oxygen in the gas. The silicon oxide layer is etchable, such as upon exposure to a hydrofluoric acid, such that the silicon oxide layer can be substantially removed, generally in accordance with the following chemical equation in which s, aq and g designate solid, aqueous and gaseous phases:
Si0₂+4HF(aq)→SiF₄(g)+2H₂0

In order to regenerate the gettering filter 12, the process is generally halted, which includes halting the flow of gas to the process chamber 14. The vessel 20 is then disengaged from the conduit 18 and an etchant, such as hydrofluoric acid, fills or is flowed through the vessel. The exposure of the pieces of oxidizable material to the etchant is continued until sufficient time has elapsed such that most, if not all, of the oxide layer formed on the pieces of oxidizable material is removed. The etchant is then drained from the vessel, the vessel is returned in line between the gas source and the process chamber, the flow of gas is recommenced and the process continues with the gettering filter more efficiently removing oxygen from the gas. Prior to returning the vessel to service after draining the etchant from the vessel, the vessel and the pieces of oxidizable material are preferably cleaned. For example, the vessel may be rinsed, such as with deionized water, and then dried, typically in conjunction with a nitrogen purge. After drying, such as for 24 hours, the vessel may be reinstalled. Following reinstallation, the vessel may be further purged at a temperature lower than the operating temperature, such as 300° C., prior to ramping the temperature to the operational temperature.

In one embodiment in which pieces 26 of silicon are utilized to remove oxygen from the gas, the resulting silicon oxide layer may be removed by exposing the pieces of silicon to hydrofluoric acid. Although hydrofluoric acid may be provided in various concentrations, the hydrofluoric acid of one embodiment is provided in a relatively dilute solution that is about 90% by weight water and 10% by weight hydrofluoric acid. Even in this diluted form, the hydrofluoric acid serves to etchably remove the silicon oxide layer formed on the pieces of silicon. The vessel 20 can then be cleaned, dried and returned to service and will more efficiently remove oxygen from the gas.

As described above, the method and apparatus 10 of the present invention effectively remove oxygen from a gas prior to introduction into a process chamber 14 in order to reduce the haze formed on the surface of the wafer 16, thereby reducing the number of wafers that must be scrapped for excessive haze and correspondingly advantageously increasing the yield of the wafer fabrication process. Additionally, the gettering filter 12 of the present invention is relatively inexpensive and does not include any components that are hazardous so as to simplify handling of the gettering filter. In this regard, the oxidizable material of the getting filter may be periodically regenerated such that the gettering filter has an indefinite life with little, if any, recurring expense.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. An apparatus comprising:
a process chamber for receiving at least one wafer; and
a gettering filter in fluid communication with said process chamber for removing oxygen from a gas that is passed through said gettering filter en route to entering said process chamber, said gettering filter comprising:
a vessel defining an inlet and an outlet through which the gas enters and exits, respectively; and
a plurality of pieces of an oxidizable material disposed within said vessel, wherein the oxidizable material is selected so as to oxidize upon exposure to oxygen in the gas such that the gas exiting said vessel through the outlet has less oxygen than the gas entering said vessel through the inlet.

2. An apparatus according to claim 1 wherein the oxidizable material is selected such that a resulting oxide layer is etchable upon exposure to an etchant.

3. An apparatus according to claim 1 wherein the oxidizable material is formed of the same material as the at least one wafer.

4. An apparatus according to claim 1 wherein the oxidizable material comprises silicon.

5. An apparatus according to claim 1 wherein said plurality of pieces of the oxidizable material have different sizes.

6. An apparatus according to claim 1 wherein said gettering filter further comprises a heater in thermal communication with said vessel to heat said plurality of pieces of the oxidizable material.

7. An apparatus according to claim 6 wherein said heater is proximate to and at least partially surrounds said vessel.

8. An apparatus according to claim 6 wherein said heater maintains said plurality of pieces of the oxidizable material at a temperature between about 600° C. and about 1200° C.

9. An apparatus according to claim 1 wherein said vessel is formed of a material that is non-reactive with the gas.

10. An apparatus according to claim 9 wherein said vessel is formed of quartz.

11. An apparatus according to claim 1 wherein said process chamber comprises a furnace.

12. A gettering filter comprising:
a vessel defining an inlet and an outlet through which gas enters and exits, respectively;
a plurality of pieces of an oxidizable material disposed within said vessel, wherein the oxidizable material is selected so as to oxidize upon exposure to oxygen in the gas such that the gas exiting said vessel through the outlet has less oxygen than the gas entering said vessel through the inlet; and
a heater in thermal communication with said vessel to heat said plurality of pieces of the oxidizable material.

13. A gettering filter according to claim 12 wherein the oxidizable material is selected such that a resulting oxide layer is etchable upon exposure to an etchant.

14. A gettering filter according to claim 12 wherein the oxidizable material comprises silicon.

15. A gettering filter according to claim 12 wherein said plurality of pieces of the oxidizable material have different sizes.

16. A gettering filter according to claim 12 wherein said heater is proximate to and at least partially surrounds said vessel.

17. A gettering filter according to claim 12 wherein said heater maintains said plurality of pieces of the oxidizable material at a temperature between about 600° C. and about 1200° C.

18. A gettering filter according to claim 12 wherein said vessel is formed of a material that is non-reactive with the gas.

19. A gettering filter according to claim 18 wherein said vessel is formed of quartz.

20. A method comprising:
flowing gas through a vessel containing a plurality of pieces of an oxidizable material;
forming an oxide layer on at least some of the pieces of oxidizable material as a result of exposure of the pieces of oxidizable material to oxygen in the gas and as the gas flows through the vessel; and
introducing the gas into a process chamber containing at least one wafer once the gas has flowed through the vessel and over at least some of the pieces of oxidizable material such that the gas introduced to the process chamber has less oxygen than the gas entering the vessel.

21. A method according to claim 20 further comprising heating the plurality of pieces of the oxidizable material while flowing gas through the vessel.

22. A method according to claim 21 wherein heating the plurality of pieces of the oxidizable material to a temperature between about 600° C. and about 1200° C.

23. A method according to claim 20 further comprising:
halting the flow of gas through the vessel;
etching the plurality of pieces of the oxidizable material to at least partially remove the oxide layer while the flow of gas through the vessel is halted; and
recommencing the flow of gas through the vessel once the plurality of pieces of the oxidizable material have been etched.

24. A method according to claim 23 wherein etching the plurality of pieces of the oxidizable material comprises exposing the plurality of pieces of the oxidizable material to an etchant.

25. A method according to claim 24 wherein the plurality of pieces of the oxidizable material comprises a plurality of pieces of silicon, and wherein exposing the plurality of pieces of the oxidizable material to an etchant comprises exposing the plurality of pieces of silicon to hydrofluoric acid.
